(19) United States
(12) Patent Application Publication
(10) Pub. No.: US 2006/0292810 A1
(43) Pub. Date: Dec. 28, 2006

(54) Method of manufacturing a capacitor

(75) Inventors: Jung-Hun Seo, Suwon-si (KR); Hyun-Young Kim, Seoul (KR); Young-Wook Park, Suwon-si (KR); Jin-Gi Hong, Suwon-si (KR); Kun-Sang Park, Suwon-si (KR); Jin-Ho Kim, Seoul (KR); Kyung-Bum Koo, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/448,769

(22) Filed: Jun. 8, 2006

(30) Foreign Application Priority Data
Jun. 27, 2005 (KR) 2005-55765

(51) Int. Cl. H01L 21/20

(52) U.S. Cl. 438/381

(57) ABSTRACT

In methods of manufacturing capacitors, a first metal compound may be deposited on a substrate using first and second source gases. The first and the second source gases may be provided onto the substrate by a first flow rate ratio in which a deposition rate of the first metal compound by surface reaction between the source gases is higher than that by mass transfer between the source gases. A second metal compound may be deposited on the first metal compound and undesired materials may be removed by providing the source gases with a second flow rate ratio different from the first flow rate ratio. Depositing the first and the second metal compounds may be repeated to form a lower electrode. A dielectric layer and an upper electrode may be formed on the lower electrode. Accordingly, permeation of an etching liquid or gas may be reduced during an etching process.

### PRIORITY STATEMENT

This application claims the benefit of priority under 35 USC § 119 to Korean Patent Application No. 2005-55765 filed on Jun. 27, 2005, the entire contents of which are herein incorporated by reference.

### BACKGROUND OF THE INVENTION

1. Field of the Invention

Example embodiments of the present invention relate to a method of manufacturing a capacitor. More particularly, example embodiments of the present invention relate to a method of manufacturing a capacitor, wherein damage to a membrane positioned below a lower electrode and/or degradation of a dielectric layer may be reduced.

2. Description of the Related Art

Semiconductor memory devices are generally formed on substrates, for example, silicon wafers by repeatedly performing a series of unit processes. Unit processes used in forming a semiconductor device may include a deposition process, an oxidation process, a photolithography process and a planarization process. A deposition process may be executed to form a layer on a substrate, and an oxidation process may be carried out to form an oxide layer on a substrate or to oxidize a layer positioned on a substrate. A photolithography process may be performed to form a desired pattern on a substrate by etching a layer positioned on the substrate, and a planarization process may be carried out to planarize a layer formed on a substrate.

Layers may be formed on a substrate using a variety of different deposition processes including, but not limited to, a chemical vapor deposition (CVD) process, a physical vapor deposition (PVD) process, an atomic layer deposition (ALD) process, etc. For example, a silicon oxide layer serving as a gate insulation layer, an insulating interlayer and/or a dielectric layer may be formed by a CVD process. A silicon nitride layer serving as a mask, an etch stop layer and/or a spacer may also be formed by a CVD process. In addition, various metal layers may be used to form metal wirings, electrodes and/or plugs of a semiconductor device, and these metal layers may be formed by a CVD process, a PVD process, and an ALD process.

In a conventional semiconductor device, a metal compound layer, for example, a titanium nitride layer may be employed for forming a plug that electrically connects a unit element to electrodes of a capacitor and/or a metal wiring. A metal compound layer may also be used as a metal barrier layer for preventing diffusion of metal atoms. A metal compound layer, for example, a titanium nitride layer may be formed by a CVD process, a PVD process, an ALD process, etc.

A conventional titanium nitride layer may be formed by a reaction between titanium chloride (TICl₄) gas and ammonia (NH₃) gas at a temperature of about 680° C. An amount of remaining chlorine (Cl) atoms in the titanium nitride layer is reduced in accordance with an increase of a process temperature for forming the titanium nitride layer. On the contrary, the titanium nitride layer has improved step coverage in accordance with a decrease of a process temperature. Accordingly, if the process temperature is augmented to reduce a content of the chlorine atoms in the titanium nitride layer, underlying structures including layers and/or patterns may be damaged by thermal stresses generated in a formation of the titanium nitride layer.

Recently, various processes have been developed to manufacture a highly integrated semiconductor device as an area of a unit cell of the semiconductor device has been reduced. For example, a gate insulation layer of a transistor or a dielectric layer of a capacitor may be formed by a process in which a high-k material is used. Additionally, an insulating interlayer of a semiconductor device may be formed by a process using a low-k material, which may reduce parasitic capacitance between the insulating interlayer and a metal wiring. Examples of the high-k material include yttrium oxide (Y₂O₃), hafnium oxide (HfO₂), zirconium oxide (ZrO₂), niobium oxide (Nb₂O₅), barium titanium oxide (BaTiO₃), strontium titanium oxide (SrTiO₃), etc.

If a titanium nitride layer is formed on a dielectric layer including hafnium oxide or zirconium oxide by the CVD process, a reaction byproduct, for example, hafnium chloride (HfCl₄) or zirconium chloride (ZrCl₄) may be generated in accordance with a reaction between the dielectric layer and a source gas, for example, the titanium chloride gas. The reaction byproduct may deteriorate dielectric and/or electrical characteristics of the dielectric layer. The reaction byproduct may increase a leakage current from the dielectric layer. The reaction byproduct may augment a specific resistance of the dielectric layer to increase a contact resistance of the capacitor.

At least in part due to the above-mentioned issues, an ALD process may be employed for forming a titanium nitride layer that serves as a dielectric layer and/or a gate insulation layer. If a titanium nitride layer is formed by the ALD process, the titanium nitride layer may have good step coverage because the titanium nitride layer may be formed at a process temperature below about 600° C. Additionally, an amount of chlorine atoms in the titanium nitride layer may decrease according to alternately providing source gases for forming the titanium nitride layer in the ALD process. However, a throughput of the titanium nitride layer may be reduced when the titanium nitride layer is formed by the ALD process.

A sequential flow deposition (SFD) process may reduce and/or solve the above-mentioned problem relating to a conventional titanium nitride layer. The SFD process may include forming a titanium nitride layer in a reaction chamber by providing TiC₄ gas and NH₃ gas, primarily purging the reaction chamber, removing chlorine atoms from the titanium nitride layer, and secondarily purging the reaction chamber. Although the SFD process may provide a throughput of a titanium nitride layer that is somewhat higher than that of the ALD process, the throughput of the titanium nitride layer provided by the SFD process is still lower than that of the CVD process.

A titanium nitride layer formed by a conventional CVD process has a columnar grain structure. Accordingly, if a titanium nitride layer formed by the CVD process is used as a lower electrode of a capacitor, permeation of an etching liquid through the lower electrode may damage a membrane positioned below the lower electrode when a mold and a sacrificial layer used for forming the lower electrode are removed after the lower electrode is formed. For example, a plug electrically connecting a transistor formed on a semiconductor substrate and a lower electrode may be damaged by permeation of an etching liquid, and an operation capacity of the semiconductor device may be deteriorated.

### SUMMARY OF THE INVENTION

Example embodiments of the present invention provide a method of manufacturing a capacitor, which may reduce and/or prevent damage to a membrane positioned below a lower electrode and/or degradation of a dielectric layer.

According to an example embodiment of the present invention, there is provided a method of forming a capacitor. In the method of manufacturing the capacitor, a first metal compound may be deposited on a substrate using a first source gas including a metal and a second source gas including an element capable of reacting with the metal. The first and the second source gases may be provided onto the substrate by a first flow rate ratio in which a deposition rate of the first metal compound by a surface reaction between the first and the second source gases may be substantially higher than a deposition rate of the first metal compound by a mass transfer between the first and the second source gases. A second metal compound may be deposited on the first metal compound and, substantially simultaneously, undesired materials may be removed from the first and the second metal compounds by providing the first and the second source gases with a second flow rate ratio substantially different from the first flow rate ratio. Depositing the first metal compound and depositing the second metal compound are alternately repeated to form a lower electrode on the substrate. A dielectric layer and an upper electrode may be sequentially formed on the lower electrode.

In an example embodiment of the present invention, the first source gas may include tetrachloride (TiCl₄), and the second source gas may include ammonia (NH₃).

In an example embodiment of the present invention, the first flow rate ratio between the first and the second source gases may be in a range of about 1.0:0.5 to about 1.0:10, and the second flow rate ratio between the first and the second source gases may be in a range of about 1.0:100 to about 1.0:1,000.

In an example embodiment of the present invention, a flow rate of the first source gas provided in a formation of the first metal compound may be substantially greater than a flow rate of the first source gas provided in a formation of the second metal compound.

In an example embodiment of the present invention, a flow rate of the second source gas provided in the formation of the second metal compound may be substantially greater than a flow rate of the second source gas provided in the formation of the first metal compound.

In an example embodiment of the present invention, a third flow rate ratio between the flow rate of the second source gas in the formation of the first metal compound and the flow rate of the second source gas in the formation of the second metal compound may be in a range of about 1.0:10 to about 1.0:100.

In an example embodiment of the present invention, the first and the second metal compounds may be deposited at a temperature within a range of about 400° C. to about 600° C.

In an example embodiment of the present invention, the first and the second metal compounds may be deposited at a temperature within a range of about 400° C. to about 700° C. and a pressure of about 0.1 Torr to about 2.5 Torr.

In an example embodiment of the present invention, the upper electrode may be formed by a process substantially similar to that of the lower electrode.

In an example embodiment of the present invention, the dielectric layer may include a material having a high dielectric constant.

In an example embodiment of the present invention, there is provided a method of forming the upper electrode. In the method of forming the upper electrode, a third metal compound may be deposited on the dielectric layer using the first source gas and the second source gas. The first and the second source gases may be provided onto the dielectric layer by a third flow rate ratio in which a deposition rate of the third metal compound by a surface reaction between the first and the second source gases is substantially higher than a deposition rate of the third metal compound by a mass transfer between the first and the second source gases. A fourth metal compound may be deposited on the third metal compound by providing the first and the second source gases with a fourth flow rate ratio substantially different from the third flow rate ratio. Depositing the third metal compound and depositing the fourth metal compound may be alternately repeated to form a first composite layer on the dielectric layer. A fifth metal compound may be deposited on the first composite layer by providing the first and the second source gases onto the first composite layer with a fifth flow rate ratio substantially different from the third flow rate ratio. The fifth metal compound may be deposited on the first composite layer in accordance with a surface reaction between the first and the second source gases. A sixth metal compound may be deposited on the fifth metal compound by providing the first and the second source gases with a sixth flow rate ratio substantially different from the fifth flow rate ratio. Depositing the fifth metal compound and depositing the sixth metal compound may be alternately repeated to form a second composite layer on the first composite layer.

In an example embodiment of the present invention, the third flow rate ratio between the first and the second source gases may be in a range of about 1.0:2.0 to about 1.0:10.

In an example embodiment of the present invention, a flow rate of the first source gas provided in a formation of the fifth metal compound may be substantially greater than a flow rate of the first source gas provided in a formation of the third metal compound.

In an example embodiment of the present invention, the fifth flow rate ratio between the first and the second source gases may be in a range of about 1.0:0.5 to about 1.0:2.0.

In an example embodiment of the present invention, the first composite layer may have a thickness of about 30 Å to about 100 Å.

In an example embodiment of the present invention, there is provided a method of forming the upper electrode. In the method of forming the upper electrode, a third metal compound may be deposited on the dielectric layer using the first and the second source gases. The first and the second source gases may be provided onto the dielectric layer by a third flow rate ratio in which a deposition rate of the third metal compound by a surface reaction between the first and the second source gases is substantially higher than a deposition rate of the third metal compound by a mass transfer between the first and the second source gases. A fourth metal compound may be deposited on the third metal compound by stopping a supply of the first source gas and by providing the second source gas with a flow rate substantially greater than a flow rate of the second source gas provided in a formation of the third metal compound. The fourth metal compound may be deposited by a reaction between the second source gas and a remaining first source gas after depositing the third metal compound. Depositing the third metal compound and depositing the fourth metal compound may be alternately repeated to form a first composite layer on the dielectric layer. A fifth metal compound may be deposited on the first composite layer by providing the first and the second source gases onto the first composite layer with a fourth flow rate ratio substantially different from the third flow rate ratio. The fifth metal compound may be deposited in accordance with a surface reaction between the first and the second source gases. A sixth metal compound may be deposited on the fifth metal compound by stopping a supply of the first source gas and by providing the second source gas with a flow rate substantially greater than a flow rate of the second source gas provided in a formation of the fifth metal compound. The sixth metal compound may be deposited by a reaction between the second source gas and a remaining first source gas after depositing the fifth metal compound. Depositing the fifth metal compound and depositing the sixth metal compound may be alternately repeated to form a second composite layer on the first composite layer.

According to an example embodiment of the present invention, there is provided a method of forming a capacitor. In the method of forming the capacitor, a first metal compound may be deposited on a substrate loaded in a process chamber using a first source gas and a second source gas. The first and the second source gases may be provided onto the substrate by a first flow rate ratio in which a deposition rate of the first metal compound by a surface reaction between the first and the second source gases is substantially higher than a deposition rate of the first metal compound by a mass transfer between the first and the second source gases. A second metal compound may be deposited on the first metal compound by stopping a supply of the first source gas and by providing the second source gas with a flow rate substantially greater than a flow rate of the second source gas provided in a formation of the first metal compound. The second metal compound may be deposited by a reaction between the second source gas and a remaining first source gas after depositing the first metal compound. Depositing the first metal compound and depositing the second metal compound may be alternately repeated to form a lower electrode. A dielectric layer and an upper electrode may be sequentially formed on the lower electrode.

According to an example embodiment of the present invention, there is provided a method of forming a capacitor. In the method of forming the capacitor, an insulation layer and a mold layer may be sequentially formed. The insulation layer may include a pad electrically connected to a semiconductor structure formed on a substrate and the mold layer may include an opening exposing the pad. A first metal compound may be deposited on the pad, an inner side face of the opening and the mold layer using first and second source gases. The first and the second source gases may be provided onto the pad, an inner side face of the opening and the mold layer by a first flow rate ratio in which a deposition rate of the first metal compound by a surface reaction between the first and the second source gases is substantially higher than a deposition rate of the first metal compound by a mass transfer between the first and the second source gases. A second metal compound may be deposited on the first metal compound and undesired materials may be substantially simultaneously removed from the first and the second metal compounds by providing the first and the second source gases with a second flow rate ratio substantially different from the first flow rate ratio. Depositing the first metal compound and depositing the second metal compound may be alternately repeated to form a composite layer of metal compound. A lower electrode electrically connected to the pad may be formed by removing a portion of the composite layer of metal compound that is positioned on an upper face of the mold layer. A dielectric layer and an upper electrode may be sequentially formed on the lower electrode.

In an example embodiment of the present invention, the method of forming the capacitor may include a sacrificial layer on a composite layer of metal compound. The sacrificial layer may fill the opening on which the composite layer of metal compound is formed. The portion of the composite layer of metal compound on the mold layer may be removed by a chemical mechanical polishing process.

In an example embodiment of the present invention, the method of forming the capacitor may include removing the mold layer and the sacrificial layer after forming the lower electrode.

### BRIEF DESCRIPTION OF THE DRAWINGS

The above and other features and/or advantages of example embodiments of the present invention will become more apparent by describing the example embodiments of the present invention with reference to the accompanying drawings, in which:

FIG. 1 is a cross-sectional view illustrating a transistor structure formed on a semiconductor device according to an example embodiment of the present invention;

FIG. 2 is a cross-sectional view illustrating first and second pads formed on the impurities regions according to an example embodiment of the present invention;

FIG. 3 is a cross-sectional view illustrating storage node pads according to an example embodiment of the present invention;

FIG. 4 is a cross-sectional view illustrating a mold layer having openings exposing storage node pads according to an example embodiment of the present invention;

FIG. 5 is a cross-sectional view illustrating a first composite layer of metal compound formed on the storage node pads and in the openings shown in FIG. 4 according to an example embodiment of the present invention;

FIG. 6 is a graph showing a deposition rate of titanium nitride layer relative to a process temperature and flow rates of provided source gases;

FIGS. 7 and 8 are graphs showing a deposition rate of a titanium nitride layer relative to a process pressure and flow rates of provided source gases;

FIG. 9 is a cross-sectional view illustrating lower electrodes formed in the openings shown in FIG. 5 according to an example embodiment of the present invention;

FIG. 10 is a cross-sectional view illustrating removing the mold layer and the sacrificial layer shown in FIG. 9 according to an example embodiment of the present invention; and

FIG. 11 is a cross-sectional view illustrating a dielectric layer and an upper electrode formed on lower electrodes according to an example embodiment of the present invention.

### DESCRIPTION OF EXAMPLE EMBODIMENTS OF THE PRESENT INVENTION

Example embodiments of the present invention are described more fully hereinafter with reference to the accompanying drawings, in which example embodiments of the present invention are shown. The present invention may, however, be embodied in many different forms and should not be construed as limited to the example embodiments of the present invention set forth herein. Rather, these example embodiments are provided so this disclosure is thorough and complete, and will fully convey the scope of the present invention to those skilled in the art. In the drawings, the sizes and relative sizes of layers and/or regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the example embodiments of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from an implanted to a non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

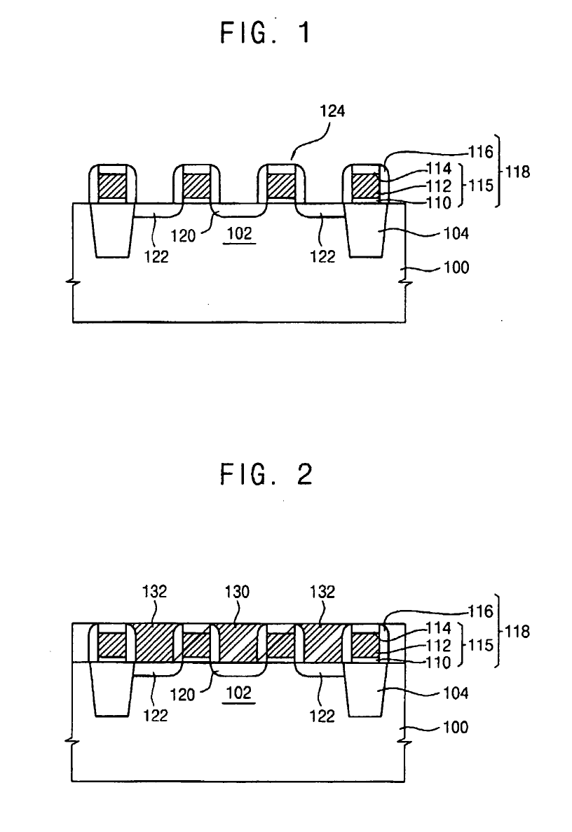

FIG 1 is a cross-sectional view illustrating a transistor structure formed on a semiconductor device according to an example embodiment of the present invention.

Referring to FIG. 1, an active region 102 and a field region (not shown) may be defined on a semiconductor substrate 100 by forming an isolation layer 104 on the semiconductor substrate 100. The semiconductor substrate 100 may include a silicon wafer. In an example embodiment of the present invention, the isolation layer 104 defining the active region 102 and the field region may be formed by a shallow trench isolation (STI) process.

A gate insulation layer (not shown) may be formed on the active regions 102 and the isolation layer 104. The gate insulation layer may be thin and may include silicon oxide. In an example embodiment of the present invention, the gate insulation layer may be formed by a thermal oxidation process and/or a chemical vapor deposition (CVD) process.

A first conductive layer (not shown) and a first mask layer (not shown) may be successively formed on the gate insulation layer. The first conductive layer and the first mask layer may be patterned to form a gate conductive layer and a gate mask layer, respectively. The first conductive layer may include polysilicon doped with impurities. Alternatively, the first conductive layer may have a polycide structure and may include a doped polysilicon film and a metal silicide film formed on the doped polysilicon film. The first mask layer may be formed using a material that has an etching selectivity relative to a first insulating interlayer (not shown) that is to be successively formed on the first mask layer. For example, the first mask layer may be formed using silicon nitride, and the first insulating interlayer may include silicon oxide.

According to an example embodiment of the present invention, after a first photoresist film (not shown) is formed on the first mask layer, the first photoresist film may be exposed and developed to form a first photoresist pattern (not shown) on the first mask layer. The first mask layer, the first conductive layer, and the gate insulation layer may be at least partially etched to form gate structures 115 on the semiconductor substrate 100 using the first photoresist pattern as an etching mask. Each of the gate structures 115 may include a gate insulation pattern 110, a word line 112, which may function as a gate electrode, and/or a gate mask pattern 114. For example, the first mask layer, the first conductive layer, and the gate insulation layer may be successively etched forming the gate structures 115 on the semiconductor substrate 100. The first photoresist pattern may be removed from the gate mask pattern 114 by an ashing and/or a stripping process.

According to an example embodiment of the present invention, a first mask layer may be anisotropically etched using a photoresist pattern as an etching mask so that a gate mask pattern 114 is formed on the first conductive layer. After the first photoresist pattern is removed from the gate mask pattern 114 by an ashing and/or a stripping process, the first conductive layer and the gate insulation layer may be successively anisotropically etched using the gate mask pattern 114 as an etching mask. Thus, the gate structures 115 including the gate insulation patterns 110, the word lines 112, and the gate mask patterns 114 may be formed on the semiconductor substrate 100.

A first spacer layer (not shown) may be formed on the semiconductor substrate 100 to at least partially cover the gate structures 115. The first spacer layer may be anisotropically etched to form gate spacers 116 on sidewalls of the gate structures 115. As shown in FIG. 2, word line structures 118 including the gate structures 115 and the gate spacers 116 may be completed on the semiconductor substrate 100.

According to an example embodiment of the present invention, impurities may be implanted through surface portions of a semiconductor substrate 100 exposed between gate structures 115, which may have gate spacers 116. The impurities may be implanted by an ion implantation process using gate structures 115 including gate spacers 116 as masks. The implanted impurities may be thermally treated to form first impurities regions 120 and second impurities regions 122 at exposed surface portions of the semiconductor substrate 100. The first and second impurities regions 120 and 122 may correspond to source/drain regions of transistors. As illustrated in FIG. 2, two of the transistors 124 in the active region 102 may share one of the first impurities regions 120.

In an example embodiment of the present invention, first and second impurities regions 120 and 122 may include impurities of relatively low concentration and impurities of relatively high concentration, respectively. In an example embodiment of the present invention, first and second impurities regions 120 and 122 may be formed before and after forming the gate spacers 116 on the sidewalls of the gate structures 115, respectively.

FIG. 2 is a cross-sectional view illustrating first and second pads formed on impurities regions shown in FIG. 1 in accordance with an example embodiment of the present invention.

Referring to FIG. 2, a first insulating interlayer (not shown) may be formed on a semiconductor substrate 100 to cover word line structures 118. The first insulating interlayer may include a silicon oxide such as boro-phosphor silicate glass (BPSG), phosphor silicate glass (PSG), undoped silicate glass (USG), spin on glass (SOG), tetraethylorthosilicate (TEOS), high density plasma-chemical vapor deposition (HDP-CVD) oxide, etc.

According to an example embodiment of the present invention, a first insulating interlayer may be formed to at least partially fill gaps between the word line structures 118. In an example embodiment of the present invention, a first insulating interlayer may be planarized by a chemical mechanical polishing (CMP) process and/or an etch back process. For example, surface portions of the first insulating interlayer may be removed by the CMP process and/or the etch back process so that the gate mask patterns 114 are exposed.

According to an example embodiment of the present invention, after a second photoresist film (not shown) is coated on the planarized first insulating interlayer, the second photoresist film may be exposed and developed to form a second photoresist pattern (not shown) on the first insulating interlayer.

According to an example embodiment of the present invention, a first insulating interlayer may be partially etched using the second photoresist patterns as an etching mask to form first and second contact holes (not shown) exposing the first and second impurities regions 120 and 122, respectively. The first and the second contact holes may be self-aligned relative to the first and the second impurities regions 120 and 122, respectively, because of an etching rate difference between the gate spacers 116 and the first insulating interlayer. The word lines 112 may be protected by the gate mask patterns 114 and the gate spacers 116.

After removing the second photoresist pattern by an ashing and/or a stripping process, a second conductive layer (not shown) may be formed on the first insulating layer and the gate mask patterns 114 to at least partially fill the first and the second contact holes. The second conductive layer may be formed using a metal nitride, for example, polysilicon doped with impurities and titanium nitride, or a metal, for example, tungsten.

According to an example embodiment of the present invention, the second conductive layer may be etched by a CMP process and/or an etch back process until the gate mask patterns 114 are exposed. Thus, first pads 130 and second pads 132, which may be electrically connected to the first impurities region 120 and the second impurities region 122, respectively, may be formed between the word line structures 118.

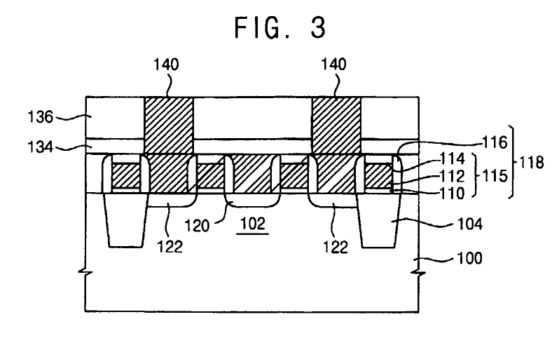

FIG. 3 is a cross-sectional view illustrating storage node pads according to an example embodiment of the present invention.

Referring to FIG. 3, a second insulating interlayer 134 may be formed on the first pads 130, the second pads 132, the gate mask patterns 114, and the first insulating interlayer. The second insulating interlayer 134 may electrically isolate word lines 112 from bit lines (not shown) successively formed on the second insulating interlayer 134. The second insulating interlayer 134 may be formed using BPSG, PSG, SOG, USG, TEOS, HDP-CVD oxide, etc. The second insulating interlayer 134 may be formed substantially the same as the first insulating interlayer, (e.g. using BPSG, PSG, SOG, USG, TEOS, and HDP-CVD). Alternatively, the second insulating interlayer 134 may be formed different from the first insulating interlayer using a BPSG, PSG, SOG, USG, TEOS, and HDP-CVD different from that of the first insulating interlayer.

After a third photoresist film (not shown) is formed on the second insulating interlayer 134, the third photoresist film may be exposed and developed to form a third photoresist pattern (not shown) on the second insulating interlayer 134 according to an example embodiment of the present invention.

The second insulating layer 134 may be anisotropically etched to form bit line contact holes (not shown) that expose the first pads 130 using the third photoresist pattern as an etching mask.

After removing the third photoresist pattern, a third conductive layer (not shown) and a second mask layer (not shown) may successively formed on the second insulating interlayer 134 according to an example embodiment of the present invention. The bit line contact holes may be at least partially filled with the third conductive layer. The second mask layer may be formed on the third conductive layer. The second mask layer may be formed using a material having an etching selectivity relative to the second insulating interlayer. The second mask layer may include silicon nitride.

The third conductive layer may be formed using a metal, for example, tungsten or a metal compound, for example, titanium nitride. In an example embodiment of the present invention, before forming the third conductive layer a metal barrier layer may be formed to prevent metal diffusion. The metal barrier layer may be formed using a metal, for example, titanium or a metal compound, for example, titanium nitride.

According to an example embodiment of the present invention, after a fourth photoresist film (not shown) is coated on the second mask layer, the fourth photoresist may be exposed and developed to form a fourth photoresist pattern (not shown) on the second mask layer. The second mask layer and the third conductive layer may be anisotropically etched successively to form bit lines (not shown) and bit line mask patterns (not shown) using the fourth photoresist pattern as an etching mask The bit lines may be electrically connected to the first pads. The bit line mask patterns may be formed on the bit lines. A bit line structure may be completed by forming bit line spacers (not shown) on side faces of the bit lines and the bit line mask patterns. The bit line spacers may be formed using a material having an etching selectivity relative to a third insulating interlayer 136 successively formed.

The third insulating interlayer 136 may be formed on the bit line structures and the second insulating interlayer 134. The third insulating interlayer 136 at least partially fill gaps between the bit line structures. The third insulating interlayer 136 may be formed using a material substantially equal to that of second insulating interlayer 134.

The third insulating interlayer 136 may be planarized by a CMP process and/or an etch back process until the bit line mask patterns are exposed.

According to an example embodiment of the present invention, after forming a fifth photoresist pattern (not shown) on the bit line mask patterns and the third insulating interlayer 136, the third insulating interlayer 136 and the second insulating interlayer 134 may be successively patterned using the fifth photoresist pattern as an etching mask to form storage node contact holes (not shown), which may expose the second pads 132. The storage node contact holes may extend to downwards, and may be self-aligned relative to the second pads 132 by the bit line structures.

According to an example embodiment of the present invention, after removing the fifth photoresist pattern, a fourth conductive layer (not shown) may be formed to at least partially fill the storage node contact holes. Storage node pads 140 filling the storage node contact holes may be completed by removing the upper portions of the fourth conductive layer until the third insulating interlayer 136 and the bit line mask patterns are exposed. The storage node pads 140 may be formed using polysilicon doped with impurities or a metal, for example, tungsten. The storage node pads 140 may electrically connect the second pads 132 to lower electrodes (not shown) that are to be formed to function as storage node electrodes.

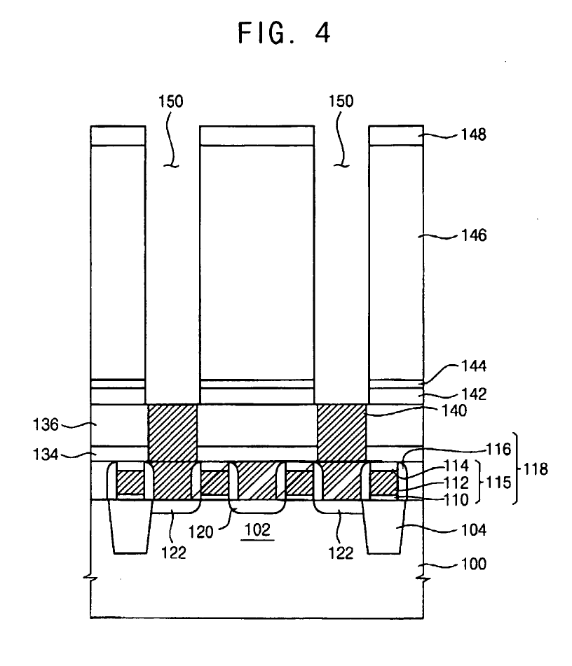

FIG. 4 is a cross-sectional view illustrating a mold layer having openings exposing storage node pads according to an example embodiment of the present invention.

Referring to FIG. 4, a fourth insulating interlayer 142 may be formed on the storage node pads 140, the bit line mask patterns, and the third insulating interlayer 136. The fourth insulating interlayer 142 may electrically isolate the bit lines from storage node electrodes of a capacitor that may be formed later. The fourth insulating interlayer 142 may be formed using a material substantially similar to the third insulating interlayer 136.

An etch stop layer 144 may be formed on the fourth insulating interlayer 142. The etch stop layer 144 may be formed using a material that has etching selectivity relative to the fourth insulating interlayer 142 and a mold layer 146 that may be subsequently formed on the fourth insulating interlayer 142. The etch stop layer 144 may include a nitride, for example, silicon nitride.

The mold layer 146 may be formed on the etch stop layer 144. The mold layer 146 may be formed using TEOS oxide, HDP-CVD oxide, PSG, USG, BPSG, SOG, etc. The mold layer 146 may have a thickness of about 5,000 Å to about 50,000 Å. Heights of the storage node electrodes may be in proportion to the thickness of the mold layer 146, and thus, the thickness of the mold layer 146 may be adjusted to control a capacitance of a capacitor.

A third mask layer (not shown) may be formed on the mold layer 146. The third mask layer may be formed using a material that has an etching selectivity relative to the mold layer 146. The third mask layer may include a nitride, for example, silicon nitride. According to an example embodiment of the present invention, the third mask layer may be formed thicker than the etch stop layer 144.

According to an example embodiment of the present invention, a sixth photoresist film (not shown) may be formed on the third mask layer, the sixth photoresist film may be exposed and developed to form a sixth photoresist pattern (not shown) on the third mask layer.

The third mask layer may be partially etched using the sixth photoresist pattern as an etching mask during an anisotropical etching process to form a storage node mask pattern 148 on the mold layer 146. The sixth photoresist pattern may be removed by an ashing and/or stripping process.

According to an example embodiment of the present invention, the mold layer 146, the etch stop layer 144 and the fourth insulating interlayer 142 may be successively etched by an anisotropical etching process using the storage node mask pattern 148 as an etching mask to form openings 150 exposing the storage node pads 140.

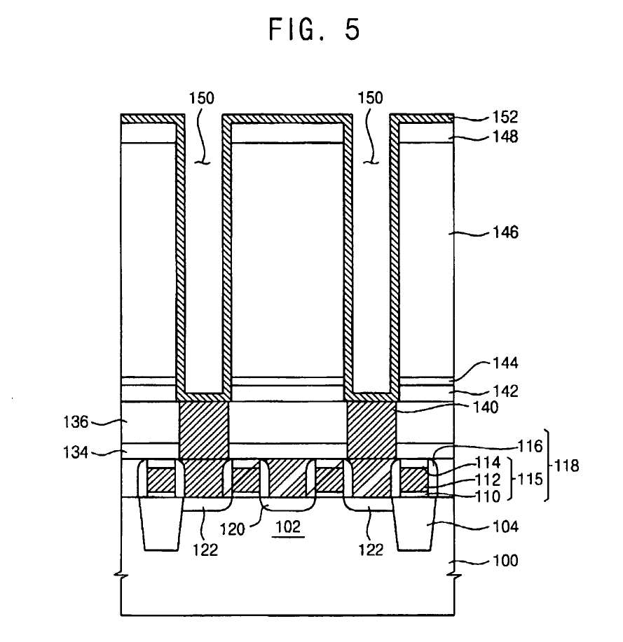

FIG. 5 is a cross-sectional view illustrating a first composite layer of metal compound formed on the storage node pads 140 and the openings 150 according to an example embodiment of the present invention.

Referring to FIG. 5, the first composite layer 152 of a metal compound is formed on the storage node pads 140, the openings 150 and the storage node mask pattern 148. The first composite layer 152 of the metal compound may include a metal nitride, for example, titanium nitride. The first composite layer 152 of the metal compound may be formed as follows.

A first metal compound may be deposited on the storage node pads 140, the openings 150 and the storage node mask pattern 148 by providing first and second source gases. According to an example embodiment of the present invention, the first metal compound may be deposited by providing a first source gas including a metal and a halogen element, and a second source gas including an element capable of being reacted with the metal and an element capable of being reacted with the halogen element on the semiconductor substrate 100 loaded in a process chamber. For example, titanium tetrachloride (TiCl₄) gas may be used as the first source gas, and ammonia (NH₃) gas may be used as the second source gas.

In depositing the first metal compound, a flow rate of the first source gas and the second source gas may be controlled by mass flow rate controllers to have a first flow rate ratio. The first flow rate ratio may be a predetermined value. In an example embodiment of the present invention, the first flow rate ratio, which is a flow rate ratio between a first flow rate associated with the first source gas and a second flow rate associated with the second source gas, may be determined to be in a range of about 1.0:0.5 to about 1.0:10. Stated differently, a flow rate ratio between the first flow rate and the second flow rate may be in a range of about 0.1:1.0 to about 2.0:1.0. According to an example embodiment of the present invention, the first source gas and the second source gases may be provided at a flow rate ratio of about 1.0:1.0. For example, both the first source gas and the second source gas may be provided at a flow rate of about 30 sccm.

If a flow rate ratio of the first flow rate to the second flow rate is smaller than about 0.1, the first metal compound may not be normally deposited. Further, if the flow rate ratio of the first flow rate to the second flow rate is greater than about 2.0, the first metal compound may be formed continuously but a use efficiency of the first source gas may be deteriorated.

According to an example embodiment of the present invention, a second metal compound may be deposited on the first metal compound and undesired materials may be substantially simultaneously removed from the first and the second metal compounds by providing the first source gas and the second source gas at a second flow rate ratio that is different from the first flow rate ratio.

According to an example embodiment of the present invention, the first source gas may be provided at a third flow rate smaller than the first flow rate, and the second source gas may be provided at a fourth flow rate greater than the second flow rate. In an example embodiment of the present invention, a second flow rate ratio, which is a flow rate ratio between the third flow rate and the fourth flow rate, may be determined to be in a range of about 1.0:100 to about 1.0:1000. If the second flow rate ratio is in a range of about 1.0:100 to about 1.0:1000 undesired materials may be sufficiently removed according to an example embodiment of the present invention. Stated differently, according to an example embodiment of the present invention, the second flow rate ratio between the third flow rate and the fourth flow rate may be determined to be within a range of about 0.001:1.0 to about 0.01:1.0. In an example embodiment of the present invention, a third flow rate ratio, which is a flow rate ratio between the second flow rate and the fourth flow rate, may be determined to be within a range of about 1.0:10 to about 1.0:100. Stated differently, the third flow rate ratio according to an example embodiment of the present invention may be determined to be within a range of about 0.01:1.0 to about 0.1:1.0. For example, in a formation of the second metal compound, the first source gas may be provided with a flow rate of about 2 sccm and the second source gas may be provided with a flow rate of about 1,000 sccm.

According to an example embodiment of the present invention, the second metal compound may be formed by a portion of the first source gas that has been provided to the process chamber and then remains in the process chamber after a formation of the first metal compound, the first source gas provided with the third flow rate, and the second source gas with the fourth flow rate. Chlorine included in the first metal compound and the second metal compound may be sufficiently removed by the second source gas provided with a flow rate greater than a flow rate with which the first source gas is provided.

By alternately repeating depositing the first metal compound and depositing the second metal compound, the first composite layer 152 of metal compound having a desired thickness may be completed according to an example embodiment of the present invention.

According to an example embodiment of the present invention, depositing the first metal compound may be performed for a first time t1, and depositing the second metal compound may be performed for a second time t2. In an example embodiment of the present invention, forming the first and the second metal compounds may be performed for about within a range from seconds to about tens of seconds,. For example, the first and the second metal compounds may be deposited for about 6 seconds.

Because chlorine may be sufficiently removed from the first and the second metal compounds as previously described with respect to an example embodiment of the present invention, the first and the second metal compounds may be deposited at a temperature relatively lower than a temperature at which first and second metal compounds including chlorine are deposited according to conventional techniques and/or devices. Thus, step coverage of the first composite layer 152 of metal compound may be improved. In an example embodiment of the present invention, the first composite layer 152 of the metal compound may be deposited at a temperature of about 400° C. to about 600° C. and a pressure of about 0.1 Torr to about 2.5 Torr.

In an example embodiment of the present invention, if the storage node pads 140 include doped polysilicon, a metal silicide layer functioning as an ohmic layer may be formed on the storage node pads 140. For example, a titanium silicide layer may be formed. In an example embodiment of the present invention, if the storage node pads 140 include a metal, for example, tungsten, a titanium layer may be formed prior to forming the first composite layer 152 of metal compound.

In an example embodiment of the present invention, in a formation of the second metal compound, a supply of the first source gas may be substantially stopped. For example, after forming the first metal compound, by stopping the supply of the first source gas and increasing the flow rate of the second source gas, the second metal compound may be formed through reaction between a first source gas remaining in the process chamber and the second source gas having an increased flow rate, and undesired materials may be removed. Stated differently, the first source gas provided in a deposition of the first metal compound may remain in the process chamber for a time after the supply of the first source gas is stopped, and may react with the second source gas with the increased flow rate to thereby deposit the second metal compound on the first metal compound.

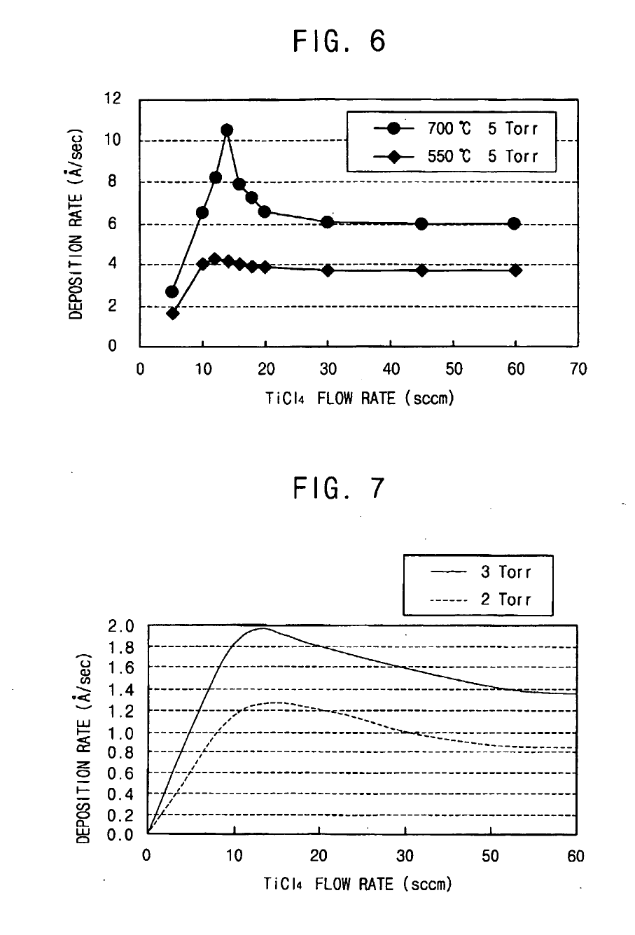

FIG 6 is a graph showing a deposition rate of titanium nitride layer relative to a process temperature and flow rates of provided source gases.

In order to evaluate a deposition rate of titanium nitride layer relative to a process temperature and flow rates of provided source gases, the deposition rate of titanium nitride layer was measured relative to a variation of flow rates of the source gases at a process temperature of about 550° C. and 700° C., respectively. As a first experiment illustrated in FIG. 6, in a state that a semiconductor substrate had a process temperature of about 550° C. by heating the semiconductor substrate, an ammonia (NH₃) gas was provided with a flow rate of about 60 sccm and the deposition rate of the titanium nitride layer was measured relative to a variation of a flow rate of a provided tetrachloride (TiCl₄) gas. As a second experiment illustrated in FIG. 6, in a state that the semiconductor substrate had a process temperature of about 700° C. by heating the semiconductor substrate, the ammonia (NH₃) gas was provided with the flow rate of about 60 sccm and the deposition rate of the titanium nitride layer was measured relative to the variation of the flow rate of the provided tetrachloride (TiCl₄) gas. A pressure of an inside of the process chamber was about 5.0 Torr in both the first and second experiments illustrated in FIG. 6. FIG. 6 illustrates the results of the first experiment and second experiment described above.

Referring to FIG. 6, at the process temperature of about 700° C., the deposition rate of the titanium nitride layer was saturated in a range in which a flow rate ratio of the tetrachloride (TiCl₄) gas to the ammonia (NH₃) gas was above about 0.5 (e.g., 0.5

represents ratio when TiC₄=30 sccm and NH₃=60 sccm), and had a steep peak value in a range in which the flow rate ratio of the tetrachloride (TiCl₄) gas to the ammonia (NH₃) gas was below about 0.5. In contrast, at the process temperature of about 550° C., the deposition rate of the titanium nitride layer did not have a steep peak value in a range in which the flow rate ratio of the tetrachloride (TiCl₄) gas to the ammonia (NH₃) gas was above or below about 0.5.

As shown in FIG. 6, at the process temperature of about 700° C., the deposition rate of the titanium nitride layer was about 6.1 Å/sec when the flow rate of the tetrachloride (TICl₄) gas was above about 30 sccm, and had a value of about 10.6 Å/sec when the flow rate of the tetrachloride (TiCl₄) gas was about 14 sccm. In contrast, at the process temperature of about 550° C., the deposition rate of the titanium nitride layer was about 3.8 Å/sec when the flow rate of the tetrachloride (TiCl₄) gas was above about 30 sccm, and had no big change when the flow rate of the tetrachloride (TiCl₄) gas was below about 30 sccm.

From the above-mentioned results, at a process temperature of about 700° C., it may be determined that a process for depositing the titanium nitride layer may not be preferably performed when the flow rate ratio of the tetrachloride (TiCl₄) gas to the ammonia (NH₃) gas is below about 0.5. Stated differently, if the flow rate ratio of the tetrachloride (TICl₄) gas to the ammonia (NH₃) gas is above about 0.5, the titanium nitride layer is primarily deposited by a surface reaction of the source gases. However, if the flow rate ratio of the tetrachloride (TICl₄) gas to the ammonia (NH₃) gas is below about 0.5, because the deposition of the titanium nitride layer on the semiconductor substrate may be affected by a matter transfer more than the surface reaction, a disadvantage in an aspect of step coverage may occur. The above-mentioned matter transfer means that after the first and the second source gases provided into the inside of the process chamber react over the semiconductor substrate, a solid-state titanium particle formed from the reaction may irregularly adhere to the semiconductor substrate. The above-mentioned surface reaction means that the first and the second source gases may react above surface portions of the semiconductor substrate to thereby form a continuous layer having a uniform thickness on the semiconductor substrate.

If the process for depositing the titanium nitride layer is affected by the matter transfer more than the surface reaction, as shown in FIG. 6, the step coverage of the titanium nitride layer may be deteriorated. On the other hand, if the process for depositing the titanium nitride layer is affected by the surface reaction, the step coverage of the titanium nitride layer may be improved.

As shown in FIG. 6, if the process temperature is about 550° C., a margin of the flow rate of the tetrachloride (TiCl₄) gas to the ammonia (NH₃) gas may be ensured. If the flow rate was above about 0.5, the deposition rate of the titanium layer was almost constant, and when the flow rate was in a range of about 0.17 to about 0.5, the deposition rate of the titanium layer may increase a little. This is because that the matter transfer occurs at a relatively low flow rate more than at a relatively high flow rate. However, because a difference between the saturated value of the deposition rate and the peak value is small, about 0.9 Å/sec, a range of an adaptable flow rate ratio at the process temperature of about 550° C. is relatively wider than that at the process temperature of about 700° C. This means that if the flow rate ratio is in a range of about 0.17 to about 0.5, the deposition process of the titanium nitride layer depends on the surface reaction more than the matter transfer, and may have a large advantage in an aspect of step coverage.

Thus, if the temperature of the process for depositing the titanium nitride layer is relatively low, the step coverage of the titanium nitride layer may be improved and the margin of the flow rate ratio of the tetrachloride (TiCl₄) gas to the ammonia (NH₃) gas may be ensured widely. Additionally, a thermal stress to a semiconductor structure positioned below the titanium nitride layer may be reduced.

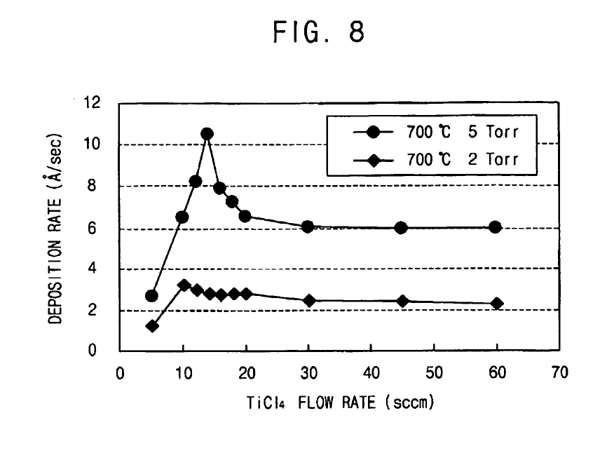

FIGS. 7 and 8 are graphs showing a deposition rate of a titanium nitride layer relative to a process pressure and flow rates of provided source gases.

In order to evaluate a deposition rate of titanium nitride relative to a process pressure and flow rates of provided source gases, a deposition rate of a titanium nitride layer was measured relative to a variation of flow rates of the source gases under a process chamber pressure of about 2.0 Torr and 3.0 Torr. As a third experiment, under a process chamber pressure of about 2.0 Torr, an ammonia gas (NH3) was provided with a flow rate of about 60 sccm and the deposition rate of the titanium nitride layer was measured relative to a variation of a flow rate of a provided tetrachloride (TiCl₄) gas. As a fourth experiment, under a process chamber pressure of about 3.0 Torr, the ammonia (NH₃) gas was provided with the flow rate of about 60 sccm and the deposition rate of the titanium nitride layer was measured relative to the variation of the flow rate of the provided tetrachloride (TiCl₄) gas. A process temperature was about 500° C. The results of the third and fourth experiments are represented as a graph in FIG. 7.

In a state that the process temperature was about 700° C., if the process chamber pressure was differently adapted with 2.0 Torr and 5.0 Torr, the deposition rate of the titanium nitride layers was measured. The results of the experiment are represented by a graph in FIG. 8.

Referring to FIG. 7, at the process chamber pressure of about 2.0 Torr and 3.0 Torr, the deposition rate of the titanium nitride layer was saturated in a range in which a flow rate ratio between the source gases is about 1.0:1.0, but the deposition rate at the process chamber pressure of about 3.0 Torr was measured higher than that at the process chamber pressure of about 2.0 Torr. In other words, the lower the process pressure was, the better step coverage of the titanium nitride layer was.

Referring to FIG. 8, a graph relative to a variation of a pressure is similar to a graph relative to a variation of a temperature shown in FIG. 6. Particularly, If the process chamber pressure is determined to be about 2.0 Torr, deposition characteristics by a surface reaction of the source gases were detected in a very wide range, and a graph representing the deposition characteristics is similar to the graph when the process pressure is about 5 Torr and the process temperature is about 550° C., as shown in FIG. 6. This means that when a thermal stress of a layer or a structure positioned below the titanium nitride layer may not need to be considered, and desired step coverage may be obtained by controlling only one of the process temperature and the process pressure according to an example embodiment of the present invention. For example, by controlling the process temperature in a range of about 400° C. to about 600° C. or by controlling the process pressure below about 4.0 Torr, the step coverage may be obtained according to an example embodiment of the present invention.

According to an example embodiment of the present invention, at least in part because the first composite layer of metal compound has a laminated composite structure, in a following etching process for removing a mold layer, permeation of an etching liquid may be restrained.

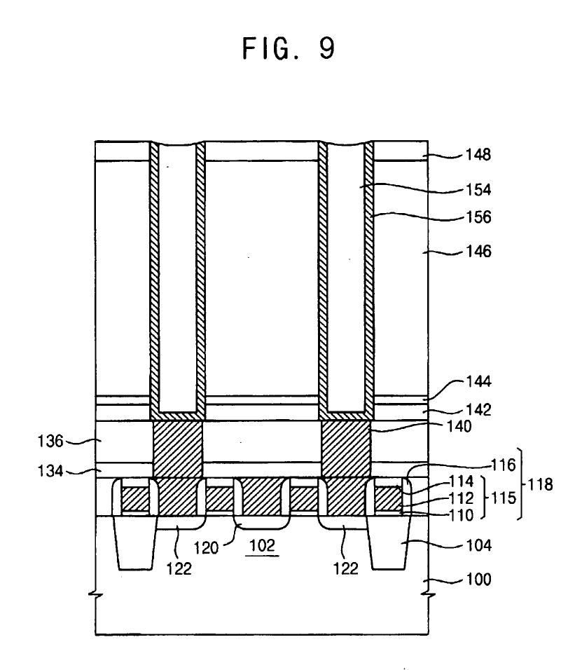

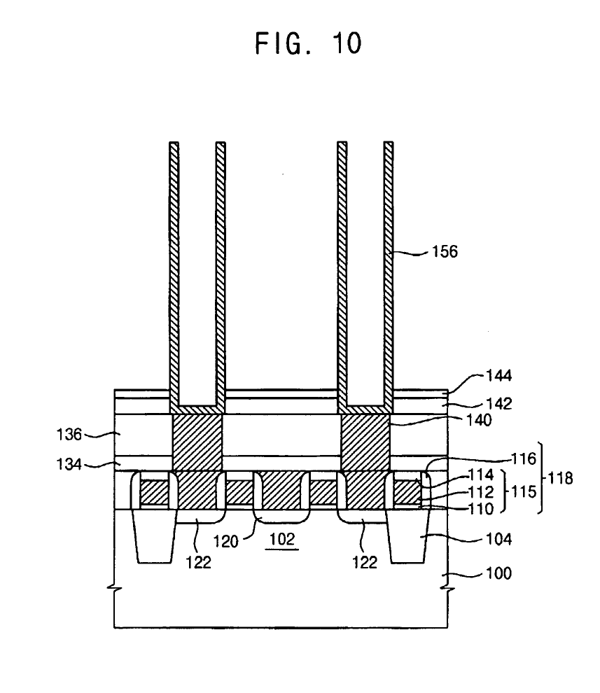

FIG. 9 is a cross-sectional view illustrating lower electrodes formed in the openings in accordance with an example embodiment of the present invention.

Referring to FIG. 9, a sacrificial layer 154 may be formed on a first composite layer 152 of metal compound to at least partially fill the openings 150. In an example embodiment of the present invention, the sacrificial layer 154 may be formed using a material substantially similar to the mold layer 146.

According to an example embodiment of the present invention lower electrodes 156 may be formed from the first composite layer 152 of metal compound by removing the sacrificial layer 154 and the first composite layer 152 of metal compound to at least partially expose the storage node mask pattern 148 using a CMP process and/or the etch back process.

A sacrificial layer 154 may be formed using photoresist according to an example embodiment of the present invention. The sacrificial layer 154 may be formed by a coating process and a bake process of photoresist composition. For example, by removing an upper portion of the sacrificial layer 154 using a whole exposure process and a developing process, and by removing an upper portion of the first composite layer 152 of metal compound using a chemical mechanical polishing process, the lower electrodes 156 may be formed on the openings 150.

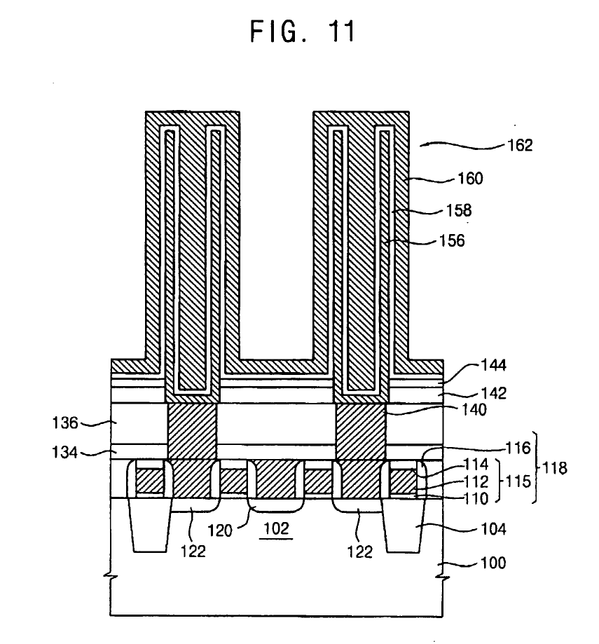

FIG 10 is a cross-sectional view illustrating removing the mold layer and the sacrificial layer as shown in an example embodiment of the present invention as illustrated in FIG. 9.

Referring to FIG. 10, surface portions of the lower electrodes 156 may be exposed by removing the storage node mask pattern 148, the mold layer 146, and/or the sacrificial layer 154.

The storage node mask pattern 148 may be removed by a wet etching process using an etching liquid including phosphoric acid, for example.

If a sacrificial layer 154 like the mold layer 146 includes silicon oxide, the mold layer 146 and the sacrificial layer 154 may be removed using LAL (Limulus Amoebocyte Lysate) solution, SC1 (Standard Clean 1) solution or hydrofluoric acid solution diluted with water at a ratio of about 100:1.0 to about 400:1.0, for example. The LAL solution may be a mixture of ammonium fluoride, hydrofluoric acid, and water. The SC1 solution may be a mixture of ammonium hydroxide, hydrogen peroxide, and water, and may be used as a cleaning liquid in manufacturing semiconductor device.

According to an example embodiment of the present invention, if the sacrificial layer 154 is formed using photoresist, the sacrificial layer 154 may be removed by an ashing and/or stripping process after removing the mold layer 146.

According to an example embodiment of the present invention, because each of the lower electrodes 156 has a laminated composite structure, permeation of the etching liquid or an etching gas into the storage node pads 140 may be reduced and/or restrained.

FIG. 11 is a cross-sectional view illustrating a dielectric layer and an upper electrode formed on lower electrodes according to an example embodiment of the present invention.

Referring to FIG. 11, a dielectric layer 158 and upper electrodes 160 may be sequentially formed on the lower electrodes 156. According to an example embodiment of the present invention, a second composite layer of metal compound may include the dielectric layer 158 and the upper electrodes 160, and may complete the formation of capacitors 162 electrically connected to the transistors 124. In an example embodiment of the present invention, a material layer having a high dielectric constant may be used as the dielectric layer 158. For example, the dielectric layer 158 may include hafnium oxide (HfO₂), zirconium oxide (ZrO₂), hafnium silicon oxide (HfSiO), zirconium silicon oxide (ZrSiO), lanthanum oxide (La₂O₃), tantalum oxide (Ta₂O₅), titanium oxide (TiO₂), strontium titanium oxide (SrTiO₃), barium strontium titanium oxide [(Ba,Sr)TiO₃], etc. In an example embodiment of the present invention, the upper electrode 160 may include a metal compound such as titanium nitride.

According to an example embodiment of the present invention, an upper electrode 160 may be formed by a method substantially similar to the method forming the lower electrodes 156. The upper electrode 160 may have a composite structure in which third metal compounds and fourth metal compounds are repeatedly, alternately laminated. Because in a formation of the third and the fourth metal compounds a halogen element, for example, chlorine may be sufficiently removed, a degradation of the dielectric layer 158 may be sufficiently reduced and/or restrained according to an example embodiment of the present invention.

In an example embodiment of the present invention, an upper electrode 160 may be formed by sequentially performing the following.

According to an example embodiment of the present invention, a third metal compound may be formed by providing the first and the second source gases at a third flow rate ratio. The third flow rate ratio may be preferably in a range in which a deposition rate by a surface reaction is greater than a deposition rate by a matter transfer to improve step coverage of the third metal compound.

A third flow rate ratio between a fifth flow rate of the first source gas and a sixth flow rate of the second source gas may be controlled to be in a range of about 1.0:2.0 to about 1.0:10. Stated differently, the third flow rate ratio between the fifth flow rate of the first source gas and the sixth flow rate of the second source gas may be controlled to be in a range of about 0.1:1.0 to about 0.5:1.0. Controlling the third flow rate ratio to have a value in the above-mentioned range may reduce contents of undesired materials, for example, chlorine, by making the fifth rate of the first source gas relatively smaller than the sixth rate of the second source gas. In an example embodiment of the present invention, the fifth flow rate of the first source gas may be about 20 sccm and the sixth flow rate of the second source gas may be about 60 sccm.

By providing the first and the second source gases with a fourth flow rate ratio substantially different from the third flow rate ratio, a fourth metal compound may be deposited on the third metal compound, and desired materials from the third and the fourth metal compounds may be removed substantially simultaneously.

Particularly, the first source gas may be provided with a seventh flow rate smaller than the fifth flow rate, and the second source gas may be provided with a eighth flow rate greater than the sixth flow rate. In an example embodiment of the present invention, the fourth flow rate ratio may be determined to be in a range of about 1.0:100 to about 1.0:100 so as to sufficiently remove the undesired materials. Stated differently, the fourth flow rate ratio between the seventh flow rate and the eighth flow rate may be determined to be in a range of about 0.001:1.0 to about 0.01:1.0. In an example embodiment of the present invention, a fifth flow rate ratio between the sixth flow rate and the eighth flow rate may be determined to be in a range of about 1.0:10 to about 1.0:100. For example, in a formation of the fourth metal compound, the first source gas may be provided with a flow rate of about 2 sccm and the second source gas is provided with a flow rate of about 1000 sccm.

By alternately repeating depositing the third metal compound and depositing the fourth metal compound, a second composite layer of metal compound with a desired thickness may be formed on the dielectric layer. The second composite layer of metal compound may be formed to have a thickness in a range of about 30 Å to about 100 Å.

By providing the first and the second source gases with a fifth flow rate ratio substantially different from the third flow rate ratio, a fifth metal compound may be deposited on the second composite of metal compound. According to an example embodiment of the present invention, the fifth flow rate ratio of a tenth flow rate of the second source gas to a ninth flow rate of the first source gas is above about 0.5, and may be controlled to be under about 2.0. For example, the fifth flow rate ratio may be controlled to be about 1.0:1.0 so that a depositing process of the fifth metal compound may be performed stably by a surface reaction between the first and the second source gases. In a deposition of the fifth metal compound, the ninth and the tenth flow rates may be controlled to be about 30 sccm.

By providing the first and the second source gases with a sixth flow rate ratio substantially different from the fifth flow rate ratio, a sixth metal compound may be deposited on the fifth metal compound, and desired materials from the fifth and the sixth metal compounds may be removed substantially simultaneously. According to an example embodiment of the present invention, the sixth flow rate ratio may be controlled to be substantially equal to the fourth flow rate.

By alternately repeating depositing the fifth metal compound and depositing the sixth metal compound in accordance with an example embodiment of the present invention, a third composite layer of metal compound with a desired thickness may be formed on the second composite layer of metal compound to complete the upper electrode 160.

In a formation of the third metal compound, by controlling the flow rate of the first source gas to be relatively small, reaction between the dielectric layer 158 and chlorine may be reduced according to an example embodiment of the present invention. If the dielectric layer 158 includes a material having a high dielectric constant, for example, hafnium oxide (HfO₂) or zirconium oxide (ZrO₂), a generation of reaction byproducts, for example, hafnium tetrachloride (HfCl₄) and zirconium tetrachloride (ZrCl₄) may be reduced and/or restrained. Accordingly, an increase of a leakage current through the dielectric layer 158 may be reduced and/or restrained.

The flow rate of the first source gas provided in a deposition of the fifth metal compound may be controlled to be greater than that in the deposition of the third metal compound. On the other hand, the flow rate of the second source gas provided in the deposition of the fifth metal compound may be controlled to be smaller than or equal to that in the deposition of the third metal compound. This is because by excluding an effect of a matter transfer on the deposition of the fifth metal compound in the formation of the fifth metal compound, the deposition of the fifth metal compound may be performed substantially only by a surface reaction between the first and the second source gases.

In an example embodiment of the present invention, in a deposition of the fourth and the sixth metal compounds, a supply of the first source gas may be substantially stopped. In this case, the fourth and the sixth metal compounds may be formed by remaining first source gas and a second source gas having an increased flow rate.

Although example embodiments of the present invention have illustrated methods of manufacturing a cylindrical capacitor until now, the methods may be adapted to methods of manufacturing a stacked capacitor.

According to example embodiments of the present invention, at least in part because lower electrodes of a capacitor may have a composite structure including first and second metal compounds, permeation of an etching liquid and/or an etching gas may be reduced and/or prevented in following process for etching a mold layer and a sacrificial layer. Accordingly, damage of the storage node pads below the lower electrodes may be reduced and/or prevented.

According to example embodiments of the present invention, because the upper electrode may have a composite structure including third and fourth metal compounds, a degradation of a dielectric layer may be reduced and/or restrained. Because a halogen element, for example, chlorine may be sufficiently removed in a formation of the third and the fourth metal compounds, reaction between the dielectric layer and chlorine may be reduced and the degradation of the dielectric layer may be reduced and/or restrained.

Furthermore, if the upper electrode is formed to have a dual structure including second and third composite layers of metal compound, the reaction between the dielectric layer and chlorine may be reduced and/or restrained at least in part due to a reduced flow rate of the first source gas in a formation of the second composite layer of metal compound.

The foregoing is illustrative of example embodiments of the present invention and is not to be construed as limiting of the present invention. Although a few example embodiments of this invention have been described, those skilled in the art will readily appreciate that many modifications are possible in the example embodiments without materially departing from the teachings and advantages of this invention. Accordingly, all such modifications are intended to be included within the scope of this invention. In the claims, means-plus-function clauses are intended to cover the structures described herein as performing the recited function and not only structural equivalents but also equivalent structures.

What is claimed is:

1. A method of forming a capacitor comprising:
depositing a first metal compound on a substrate using a first source gas including a metal and a second source gas including an element reacting with the metal, wherein the first and the second source gases are provided onto the substrate by a first flow rate ratio;
depositing a second metal compound on the first metal compound by providing the first and the second source gases with a second flow rate ratio substantially different from the first flow rate ratio;
alternately repeating depositing the first metal compound and depositing the second metal compound to form a lower electrode on the substrate; and
sequentially forming a dielectric layer and an upper electrode on the lower electrode.

2. The method of claim 1, wherein a deposition rate of the first metal compound by a surface reaction between the first source gas and the second source gas is substantially higher than a deposition rate of the first metal compound by a mass transfer between the first source gas and the second source gas.

3. The method of claim 1, wherein depositing the second metal compound includes removing undesired materials from the first metal compound and the second metal compound substantially simultaneously with depositing the second metal compound.

4. The method of claim 1, wherein the first source gas comprises titanium tetrachloride (TiCl₄), and the second source gas comprises ammonia (NH₃).

5. The method of claim 1, wherein the first flow rate ratio between the first and the second source gases is in a range of about 1.0:0.5 to about 1.0:10, and the second flow rate ratio between the first and the second source gases is in a range of about 1.0:100 to about 1.0:1,000.

6. The method of claim 1, wherein a flow rate of the first source gas provided in a formation of the first metal compound is substantially greater than a flow rate of the first source gas provided in a formation of the second metal compound.

7. The method of claim 1, wherein a flow rate of the second source gas provided in the formation of the second metal compound is substantially greater than a flow rate of the second source gas provided in the formation of the first metal compound.

8. The method of claim 7, wherein a third flow rate ratio between the flow rate of the second source gas in the formation of the first metal compound and the flow rate of the second source gas in the formation of the second metal compound is in a range of about 1.0:10 to about 1.0:100.

9. The method of claim 1, wherein the first and the second metal compounds are deposited at a temperature of about 400° C. to about 600° C.

10. The method of claim 1, wherein the first and the second metal compounds are deposited at a temperature of about 400° C. to about 700° C. and a pressure of about 0.1 Torr to about 2.5 Torr.

11. The method of claim 1, wherein the upper electrode is formed by a process substantially similar to a process of forming the lower electrode.

12. The method of claim 1, wherein the dielectric layer includes a material having a high dielectric constant.

13. The method of claim 12, wherein forming the upper electrode comprises:
depositing a third metal compound on the dielectric layer using the first source gas and the second source gas, wherein the first and the second source gases are provided onto the dielectric layer by a third flow rate ratio in which a deposition rate of the third metal compound by a surface reaction between the first and the second source gases is higher than a deposition rate of the third metal compound by a mass transfer between the first and the second source gases;
depositing a fourth metal compound on the third metal compound by providing the first and the second source gases with a fourth flow rate ratio different from the third flow rate ratio;
alternately repeating depositing the third metal compound and depositing the fourth metal compound to form a first composite layer on the dielectric layer;
depositing a fifth metal compound on the first composite layer by providing the first and the second source gases onto the first composite layer with a fifth flow rate ratio different from the third flow rate ratio, wherein the fifth metal compound is deposited on the first composite layer in accordance with a surface reaction between the first and the second source gases;
depositing a sixth metal compound on the fifth metal compound by providing the first and the second source gases with a sixth flow rate ratio different from the fifth flow rate ratio; and
alternately repeating depositing the fifth metal compound and depositing the sixth metal compound to form a second composite layer on the first composite layer.

14. The method of claim 13, wherein the third flow rate ratio between the first and the second source gases is in a range of about 1.0:2.0 to about 1.0:10.

15. The method of claim 13, wherein a flow rate of the first source gas provided in a formation of the fifth metal compound is substantially greater than a flow rate of the first source gas provided in a formation of the third metal compound.

16. The method of claim 13, wherein the fifth flow rate ratio between the first and the second source gases is in a range of about 1.0:0.5 to about 1.0:2.0.

17. The method of claim 13, wherein the first composite layer has a thickness of about 30 Å to about 100 Å.

18. The method of claim 12, wherein forming the upper electrode comprises:
depositing a third metal compound on the dielectric layer using the first and the second source gases, wherein the first and the second source gases are provided onto the dielectric layer by a third flow rate ratio in which a deposition rate of the third metal compound by a surface reaction between the first and the second source gases is higher than a deposition rate of the third metal compound by a mass transfer between the first and the second source gases;
depositing a fourth metal compound on the third metal compound by stopping a supply of the first source gas and by providing the second source gas with a flow rate greater than a flow rate of the second source gas provided in a formation of the third metal compound, wherein the fourth metal compound is deposited by a reaction between the second source gas and a remaining amount of first source gas after depositing the third metal compound;
alternately repeating depositing the third metal compound and depositing the fourth metal compound to form a first composite layer on the dielectric layer;
depositing a fifth metal compound on the first composite layer by providing the first and the second source gases onto the first composite layer with a fourth flow rate ratio different from the third flow rate ratio, wherein the fifth metal compound is deposited in accordance with a surface reaction between the first and the second source gases;
depositing a sixth metal compound on the fifth metal compound by stopping a supply of the first source gas and by providing the second source gas with a flow rate greater than a flow rate of the second source gas provided in a formation of the fifth metal compound, wherein the sixth metal compound is deposited by a reaction between the second source gas and a remaining amount of first source gas after depositing the fifth metal compound; and
alternately repeating depositing the fifth metal compound and depositing the sixth metal compound to form a second composite layer on the first composite layer.

19. A method of forming a capacitor comprising:
depositing a first metal compound on a substrate loaded in a process chamber using a first source gas and a second source gas, wherein the first and the second source gases are provided onto the substrate by a first flow rate ratio in which a deposition rate of the first metal compound by a surface reaction between the first and the second source gases is higher than a deposition rate of the first metal compound by a mass transfer between the first and the second source gases;
depositing a second metal compound on the first metal compound by stopping a supply of the first source gas and by providing the second source gas with a flow rate greater than a flow rate of the second source gas provided in a formation of the first metal compound, wherein the second metal compound is deposited by a reaction between the second source gas and a remaining amount of first source gas after depositing the first metal compound;
alternately repeating depositing the first metal compound and depositing the second metal compound to form a lower electrode; and
sequentially forming a dielectric layer and an upper electrode on the lower electrode.

20. A method of forming a capacitor comprising:
sequentially forming an insulation layer and a mold layer, wherein the insulation layer comprises a pad electrically connected to a semiconductor structure formed on a substrate and the mold layer comprises an opening exposing the pad;
depositing a first metal compound on the pad, an inner side face of the opening and the mold layer using a first source gas and a second source gas, wherein the first and the second source gases are provided onto the pad, an inner side face of the opening and the mold layer by a first flow rate ratio in which a deposition rate of the first metal compound by a surface reaction between the first and the second source gases is higher than a deposition rate of the first metal compound by a mass transfer between the first and the second source gases;
depositing a second metal compound on the first metal compound and removing undesired materials from the first and the second metal compounds by providing the first and the second source gases with a second flow rate ratio different from the first flow rate ratio;
alternately repeating depositing the first metal compound and depositing the second metal compound to form a composite layer of metal compound;
forming a lower electrode electrically connected to the pad by removing a portion of the composite layer of metal compound, the portion being positioned on an upper face of the mold layer; and
sequentially forming a dielectric layer and an upper electrode on the lower electrode.

21. The method of claim 20, further comprising:
filling the opening on which the composite layer of metal compound is formed with a sacrificial layer; and
removing the portion of the composite layer of metal compound on the mold layer by a chemical mechanical polishing process.

22. The method of claim 21, wherein the mold layer and the sacrificial layer is removed after forming the lower electrode.
